(19) United States
(12) Patent Application Publication
(10) Pub. No.: US 2026/0252452 A1
(43) Pub. Date: Aug. 27, 2026

(54) SERVICE PREDICTOR FOR TEST AND MEASUREMENT INSTRUMENTS

(71) Applicant: Tektronix, Inc., Beaverton, OR (US)

(72) Inventors: Jatinkumar Vrajlal Domadiya, Bengaluru (IN); Srevats S. Laxman, Bengaluru (IN); Madhusudan Acharya, Bengaluru (IN)

(21) Appl. No.: 19/544,478

(22) Filed: Feb. 19, 2026

Related U.S. Application Data
(60) Provisional application No. 63/763,591, filed on Feb. 26, 2025.

(51) Int. Cl. G06F 11/27; G06F 11/273

(52) U.S. Cl. CPC G06F 11/27; G06F 11/273

(57) ABSTRACT

A test and measurement instrument includes hardware components, comprising one or more of: one or more system circuit boards, a user interface, a display, a power supply, one or more integrated circuit chips, and a memory, one or more artificial intelligence (AI) models stored in the memory, and one or more processors configured to execute code to cause the one or more processors to operate one of the one or more AI models to receive inputs from at least one of the hardware components and provide an output of predicted service needs for the test and measurement instrument.

### CROSS-REFERENCE TO RELATED APPLICATIONS

This disclosure is a non-provisional of and claims benefit from U.S. Provisional Application No. 63/763,591, titled “SERVICE PREDICTOR FOR TEST AND MEASUREMENT INSTRUMENTS,” filed on Feb. 26, 2025, the disclosure of which is incorporated herein by reference in its entirety.

### TECHNICAL FIELD

This disclosure relates to test and measurement instruments, and more particularly to systems and methods for predicting hardware failures or other service needs for a test and measurement instrument, such as an oscilloscope.

### BACKGROUND

Hardware failure of a test and measurement instrument, such as an oscilloscope, can depend on various conditions and parameters. To ensure timely repairs for customers' instruments, service teams need to maintain a list of hardware stock for future repairs. If the required hardware is not available, customers may need to wait for a long time to get their instrument back, which could disrupt their work.

Calibration is another area where customers may need to send their instrument for lab calibration. This is a periodic recommendation made by manufacturers of oscilloscope instruments. Depending on oscilloscope model, the customer may need to opt for lab or in-house calibration. Calibration is generally dependent on various parameters such as usage of the instrument, temperature range, and instrument's hardware performance. Therefore, customers need to decide on the calibration needs, which can be unpredictable. Any sudden failure of accuracy of the measurement result can stop the customer from using the instrument further without any prior plan.

### BRIEF DESCRIPTION OF THE DRAWINGS

FIG. 1 shows an embodiment of a test and measurement instrument.

FIG. 2 shows a graph of instrument usage versus instrument age and the probability of failure.

FIG. 3 shows a graph of instrument noise versus system age in oscilloscopes.

FIG. 4 shows an embodiment of input parameters to a neural network in an embodiment of a model used to predict hardware health.

FIGS. 5A-5B show training error trends.

FIGS. 6A-6B show prediction with training data sets corresponding to the training error trends in FIGS. 5A-5B.

FIGS. 7A-7B show predictions respective to test data.

FIG. 8 shows a graph of prediction efficiency with training and test data.

FIG. 9 shows a view of an embodiment of a user interface for a health monitoring system.

FIG. 10 shows another view of an embodiment of a user interface for a health monitoring system.

FIG. 11 shows an interface for internal hardware and calibration health prediction output.

### DETAILED DESCRIPTION

Generally, embodiments of the disclosure operate to predict the internal hardware health for detecting early hardware failure of a test and measurement instrument. Predicting “service needs” for an instrument, as used in this disclosure, may include both predicting the need for a repair, including a preemptive repair of a component, as well as the need for calibration of the instrument or a component of the instrument. The term “service needs,” or “service need,” as used herein encompasses all these aspects of the instrument and its components.

Embodiments of the disclosure also generally enable the advanced detection of an instrument's calibration needs. An artificial intelligence model, referred to herein as the “model,” or “AI model,” will predict the calibration health as a percentage. If the calibration health drops below a specific percentage, it indicates that the system requires calibration, either at customer site or at service depot, such as the instrument supplier's lab or other facility.

Additionally, some embodiments of the disclosure may also include a model where data from each instrument's health monitoring system can be fetched and stored in a central server system. This system will contain information about the location of the device, as well as the health and calibration prediction information for each device in the market. The service team can utilize this system to assess the internal hardware health of various instruments in the market. They will also be able to segregate the data based on region.

In an example, assume that currently, customers are using 2034 mixed-signal oscilloscopes (MSO). By consolidating each oscilloscope's health prediction report, the service team will know that the PSU (power supply unit) of the main board or carrier board of 100 units is below 70%. This indicates that the service team may expect 100 units of MSO oscilloscopes in a specific region to require repair due to specific hardware failure. The same is true for the calibration of the instrument. The system of the embodiments may assist the service team in scheduling and procuring replacement parts and planning for appropriate capacity for test and calibration stations.

The embodiments disclosed here build one or more AI models on top of this data. This neural network-based model will help to predict future requirements and demand.

This will assist in making critical decisions for future requirements that are in the pipeline for new development scopes in the factory. For instance, one can determine the current quantities of a particular instrument in the market along with their health statuses. This information can then be used to forecast the future demand for those instruments in the market.

This approach aids in focusing on specific hardware efficiency improvements, providing the ability to address hardware issues and strategize for future enhancements. As a result, instrument manufacturers can create instruments with higher reliability, more stability, and having a longer lifespan.

The following discussion illustrates some example embodiments in the context of a Tektronix Mixed Signal Oscilloscope (MSO) series oscilloscope health predictor. However, embodiments of the disclosure are not limited to this example, which is for ease of understanding. The approach in the embodiments apply to any type of instrument.

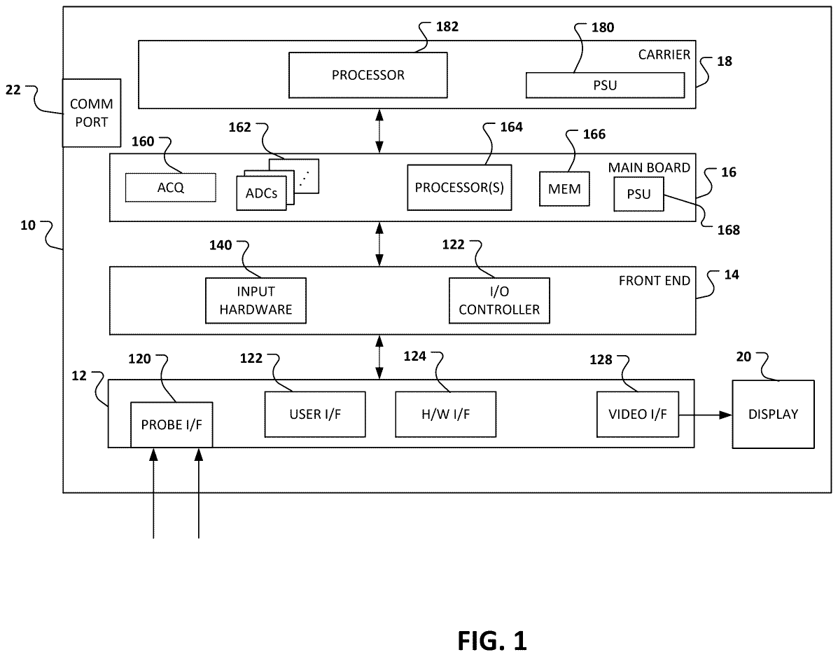

FIG. 1 shows a generalized view of an MSO 10, with the understanding that many of the boards, individual components and processors represent these same components in any instrument. The MSO has several system boards, generally printed circuit boards (PCB), but may comprise any type of substrate upon which the processors and integrated circuit chips may reside and may comprise only one board. The MSO may have a front panel 12 that includes an interface 120 for probes that may be used in testing, a user interface 122 that may include user controls, such as knobs, buttons, switches, key pad(s), etc., or any other type of control that allows a user to input information and make selections. The display 20 may comprise a touch screen that may incorporate some or all the user controls. Hardware interface 124 may include integrated circuits that provide compensation signals for the probe inputs, as well as interfaces for other hardware such as USB ports, accessory video ports, etc. The video interface 128 comprises the necessary components to allow presentation of the incoming data on display 20. Communications port 22 provides a communication or network interface and allows the instrument to set up communication connection(s) and communication across networks, including near-field networks, wi-fi networks, cellular networks, etc. This allows the instrument to send, or a service center server to request, health check data, as will be discussed in more detail below. The various components in each subsystem may connect directly to each other or through other components not shown.

Front end 14 may include components 140 that operate on the incoming signals from the probes or other inputs from devices under test (DUT), including but not limited to, attenuators, preamplifiers, and amplifiers. The front end may also include a controller, or processor, 122 to manage inputs and outputs from the MSO.

Main board 16 may include acquisition hardware components 160 such as digitizers, etc., and analog-to-digital converters (ADCs) 162, for when the signals are analog to convert them into digital signals for display and analysis. The acquisition hardware may also include trigger circuitry and signal conditioning circuits for filtering signals, etc. The main board will also include one or more processors 164 and memory 166. Many of the other boards may include various types of memory as well, but for purposes of simplicity the memory 166 represents all memory in instrument 10.

The carrier board 18 generally contains the power supply unit (PSU) 180 that provides power to the other boards. The main board 16 may include PSU circuitry 168 to convert the incoming power, such as 12V DC, to various voltage levels as needed. The main board, and in some instances the carrier board, may include one or more processors 164 and 182. The one or more processors are configured to execute code to cause the one or more processors to perform various tasks and functions within the device.

Table-1 lists internal hardware model of MSO series oscilloscope as a summary. Additionally, some embodiments may use a built-in known signal source of “Probe Compensation.” According to embodiments of the invention, an AI-based model with various input parameters can predict the early failure of specific hardware. Timely prediction of hardware failure will help customers plan their work with the instrument. The embodiments assess the health of various internal hardware boards and calibration.

TABLE 1
List of Internal Hardware of MSO series oscilloscope

| Hardware Name | Description |
|---|---|
| Carrier Processor Board | It is responsible to bridge between |
| | various functional boards on oscilloscope |
| Power Distribution Or | It converts the input AC power to various |
| PSU of Carrier Board | DC power levels. |
| Front Panel | Knobs and Microcontroller, Probe |
| | compensation Board |
| Main Board | It acquires the signal from channels and |
| | includes triggering functionality as well. |
| Main Board PSU | It converts +12V DC to various other |
| | voltage levels. Some of them are used for |
| | Amplification and attenuation inside |
| | Front End Board. |
| Front End | It contains the analog path and its related |
| | ASIC(s). |

According to an example embodiment of the disclosure, a neural network model is used that is based on a list of input parameters, such as the example provided below. This model will be trained to monitor the health of individual hardware components and predict potential failures

TABLE 2
Parameter list

| Index | Parameter | Description |
|---|---|---|
| 1 | Oscilloscope Age | Age of Oscilloscope, when it is manufactured or |
| | | it has been started using by customer. |
| 2 | SPC | Signal Path Compensation (SPC) status query |
| 3 | Scope Noise | Measures the scope noise on each channel |
| 4 | Voltage minimum | Measures the minimum voltage on each channel. |
| | | Input source is the in-built Probe compensation output. |
| 5 | Voltage maximum | Measures the maximum voltage on each channel. |
| | | Input source is the in-built Probe compensation output. |
| 6 | Rise Time | Measures the rise time on each channel. Input |
| | | source is the in-built known Probe compensation output. |
| 7 | Fall Time | Measures the fall time on each channel. Input |
| | | source is the in-built Probe compensation output. |
| 8 | Frequency | Measures the frequency on each channel. Input |
| | | source is the in-built Probe compensation output. |
| 9 | TEMP: Custom ASIC | Measured temperature on custom acquisition |
| | ADC | ASIC. |
| 10 | TEMP: Custom ASIC | Measured temperature of fan controller diode. |
| | fan control diode | |
| 11 | Display Color | Checks for display RGB color change |
| 12 | Delta Scope Noise | Measures the scope noise deviation between two |
| | | runs of Tektronix Oscilloscope Health Predictor solution. |
| 13 | Delta Volt min | Measures the minimum voltage deviation |
| | | between two runs of Tektronix Oscilloscope Health |
| | | Predictor solution. |
| 14 | Delta Volt Max | Measures the maximum voltage deviation |
| | | between two runs of Tektronix Oscilloscope Health |
| | | Predictor solution. |
| 15 | Delta Rise Time | Measures the rise time deviation between two |
| | | runs of Tektronix Oscilloscope Health Predictor solution. |
| 16 | Delta Fall Time | Measures the fall time deviation between two |
| | | runs of Tektronix Oscilloscope Health Predictor solution. |
| 17 | Delta Freq | Measures the frequency deviation between two |
| | | runs of Tektronix Oscilloscope Health Predictor solution. |
| 18 | Delta ADC Temp | Measures the ADC temp deviation between two |
| | | runs of Tektronix Oscilloscope Health Predictor solution. |
| 19 | Delta Diode Temp | Measures the Diode temperature deviation |
| | | between two runs of Tektronix Oscilloscope Health |
| | | Predictor solution. |
| 20 | IO | MSO scope in built Self-Test Input Output Port |
| | | testing. |
| 21 | Front Panel | MSO's Self Test:: Communicate to the Front |
| | | Panel's Digital Communication Board only. |
| 22 | Analog | MSO's Self Test: Analog test sends the signal to |
| | | “Front-End” and checks the amplification and |
| | | attenuation functionality of front end ASIC(s). |
| 23 | System | MSO's Self Test:: Test for register |
| | | communication, voltage level, temperature, power up |
| 24 | ASIC | MSO's Self Test:: Memory of Custom ASIC, |
| | | Acquisition of Custom ASIC (ADC) |
| 25 | Acquisition | MSO's Self Test:: Internally FGPA sends the |
| | | signal to “Main Board” and check functionalities of the |
| | | Acquisition system. AC Line trigger, Over Load (50 |
| | | Ohm, 1M ), Control line |
| 26 | Signal | MSO's Self-Test:: Sin Wave Test, Sin Wave Test |
| | | Post, Swept Sine Test, High Frequency Step, Offset |
| | | DAC, CVR DC Check, Null DAC Check, input Offset |
| 27 | Memory | MSO's Self-Test:: Custom ASIC Memory |
| | | (Acquisition Memory DRAM) |

One should note that the list of input parameters in the above table only represent examples. Input parameters can be reduced, or expanded in other embodiments to include more parameters as Fan RPM speed, FAN voltage, PSU output voltage, temperature stress duration, etc. Some model selections, discussed in more detail later, may depend upon which input parameters for a particular instrument are available.

The importance of each parameter used as an input is as follows.

SPC Status helps with the correctness of other measured parameters. Example, when the scope noise of de-skew source parameters is measured and SPC status is RED, the measured parameters cannot be considered for the input of the neural network.

Temperature of Custom ASIC will generally be exposed in the self-test logs. This may apply to the temperature inside of a custom ASIC, e.g., a custom ASIC ADC. High temperature causes higher deviation of measured value with respect to its expected value. The same holds true for the fan controller diode's temperature.

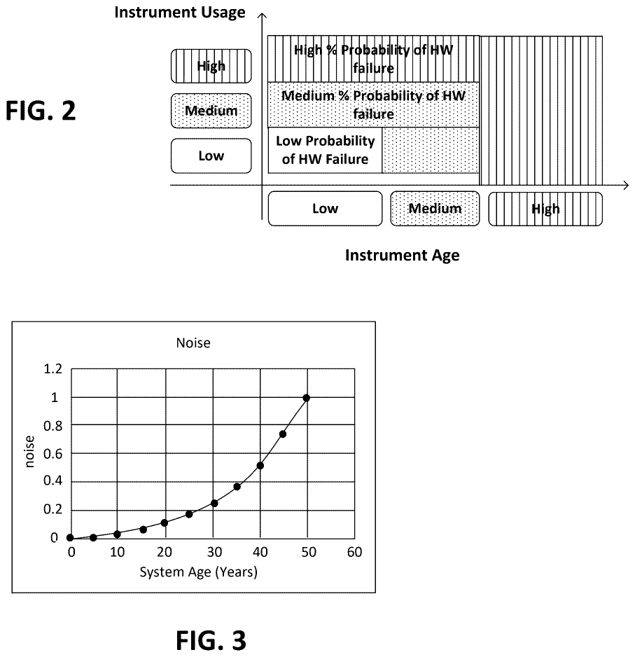

System usage and Age will be used to train the neural network on aging of the hardware as time goes by. As the age of the electronic hardware increase, their components will become weaker. Hardware reliability reduces with their usage and age. FIG. 2 shows a graphic of the relationship between instrument usage, instrument age, and the likelihood of hardware failures. The embodiments measure how long a particular instrument is used. As instrument usage increases, the hardware failure possibility also increases. Additionally, frequent calibration may be necessary to ensure that the system is functioning optimally and providing accurate information to users.

The model of the embodiments has trained on the exponential decay function to train the model. This function considers the probability of instrument aging, as a parameter for the model. FIG. 3 shows an example of an exponential model that shows the relationship between the instrument age and the noise experienced in the instrument.

Many instruments, including MSOs, have instrument service self-tests that a user can perform, either at the customer site or at a service depot. The result of the self-test has high correlation with individual hardware health and its performance. The self-test data has also been used to train the model(s).

MSO series oscilloscopes have inbuilt “Probe Compensation,” which generates the square wave with fast edge of 1 KHZ signal with voltage level of +/−1.25 volts. One can use this as a known source and measure the input parameter on each channel from index 4 to 8 from above table. While this particular feature is unique to MSOs, other instruments have abilities to generate know source signals to compensate and/or calibrate the instrument.

Using the known source signal, one can measure aspects of the instrument's operation such as voltage, fundamental frequency, rise/fall times, etc. These allow the user and/or the model to use the results for these parameters to make judgments as to the instrument's operations. For example, if the measured voltage (Min, Max), fundamental frequency, or rise/fall time deviate from the expected values, it may indicate one or more of the following possibilities. The instrument may require calibration, acquisition hardware within the instrument may have failed, and/or the power distribution within the instrument may have failed. The integral power distribution of the instrument also powers the ‘Probe Compensation.’ If the power supply has a failure in supplying power to this component, it could result in an incorrect voltage output. Further, if an issue exists with power distribution, it may impact jitter on “Differential Fast Edge” sources. Further, there may be a front channel acquisition issue, meaning that an issue exists with the probe interface.

Scope noise RMS is measured when no signal connected to oscilloscope. If the measured scope noise rms value is high, such as the values for Ch1 and Ch4 below, it indicates one or more of the following possibilities. An issue may exist with the front panel hardware such as an acquisition board for a specific channel acquisition has an issue. An issue may exist in the SPC path calibration. The Main or Carrier board PSU may have an issue.

| Channel | Scope Noise rms Value |
|---|---|
| Ch-1 | 114 mVrms |
| Ch-2 | 3 mVRms |
| Ch-3 | 4 mVRms |
| Ch-4 | 103 mVrms |

The embodiments herein have developed a neural network model for each type of instrument. In one particular example, the neural network has an architecture with 25 input layers, 12 hidden layers and 1 output layer. The output layer outputs the value. The activation function that introduces non-linearity comprises a tanh (hyperbolic tangent) function, with no output layer activation. Other activation functions may be used. This embodiment uses least mean square error (LMSE) as the loss function.

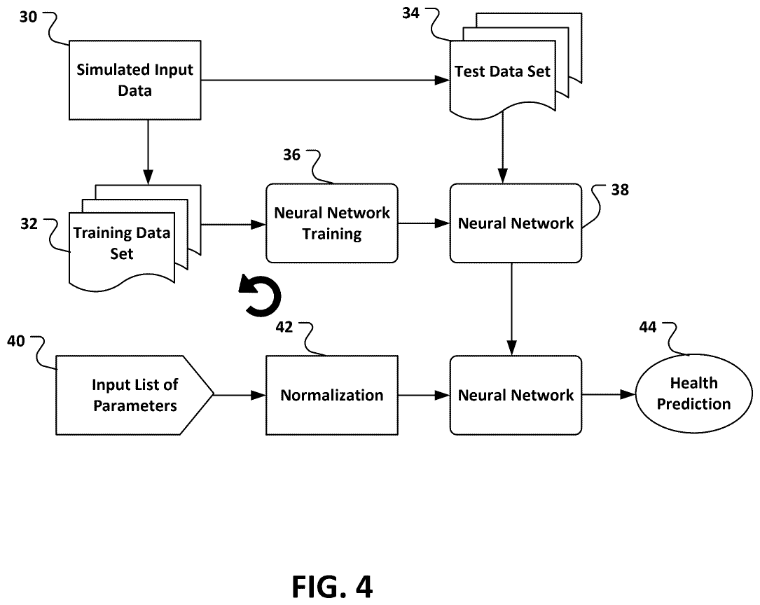

FIG. 4 shows an embodiment of the overall system used for training and running the model for determining service needs of a given instrument.

The model trained on a data set of simulated samples 30. In a particular embodiment, 8000 simulated samples were generated, with 40% chosen as a training data set 32, with the remaining data being reserved as a test data set 34 for testing of the model. The training process 36 iterates until the results reach a high enough level of probability when run on the test data set 34, resulting in the trained neural network 38. In operation, the input parameters 40 undergo normalization at 42 after which the neural network 38 operates on the inputs to provide a health prediction at 44. As discussed above, the health prediction comprises some type of service need, or that no service is needed. The service need may comprise calibration status indicating that the instrument needs calibration, that there are components, such as boards, chips, processors, etc., that are failing, or an indication that there are some components that are approaching a high likelihood of failure.

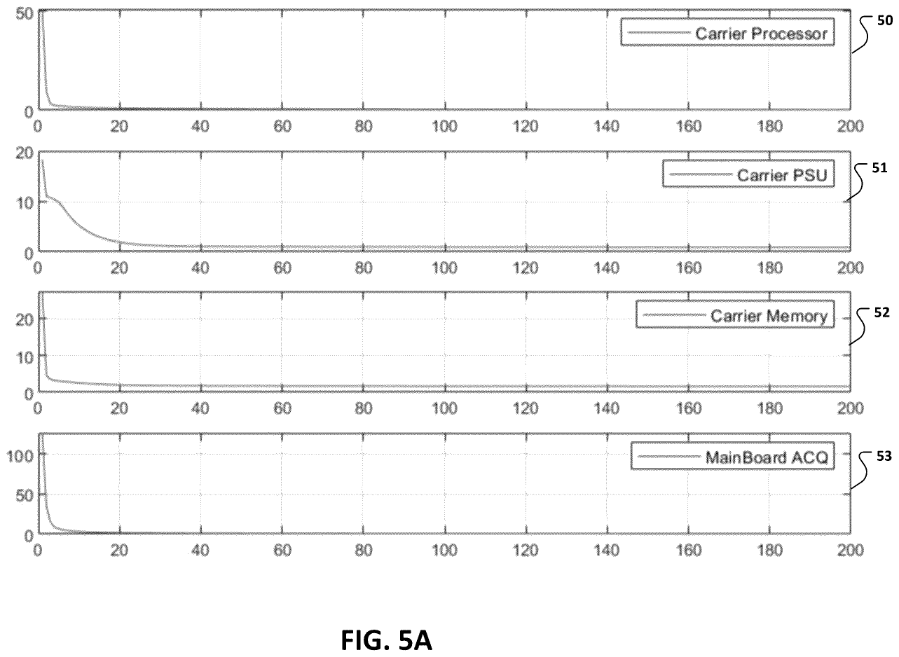

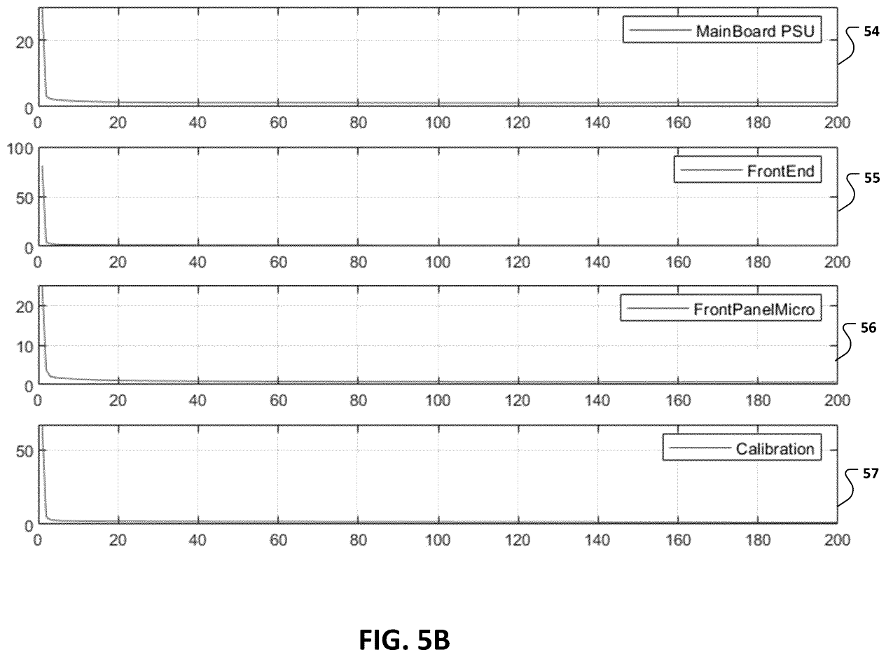

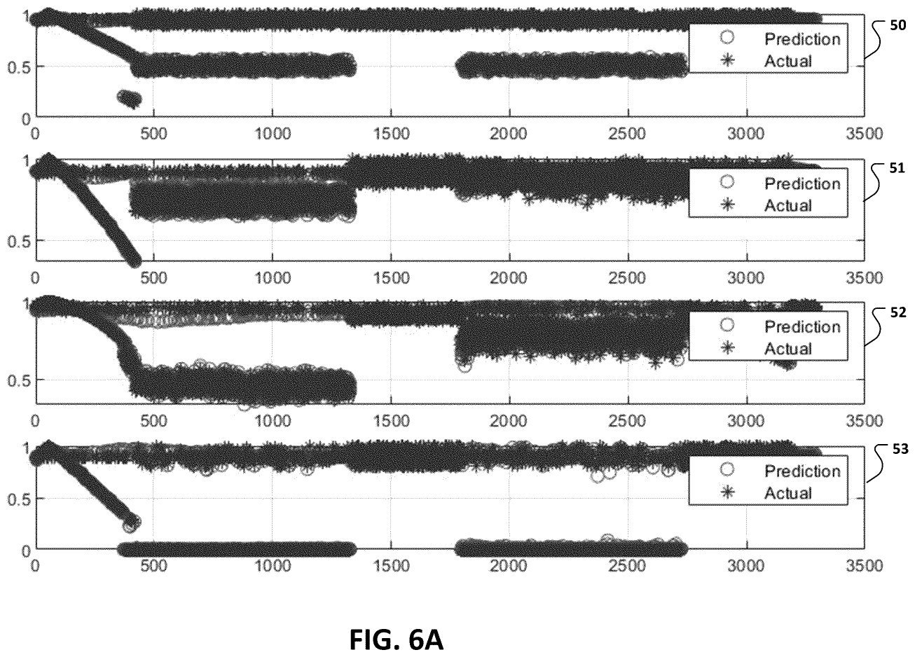

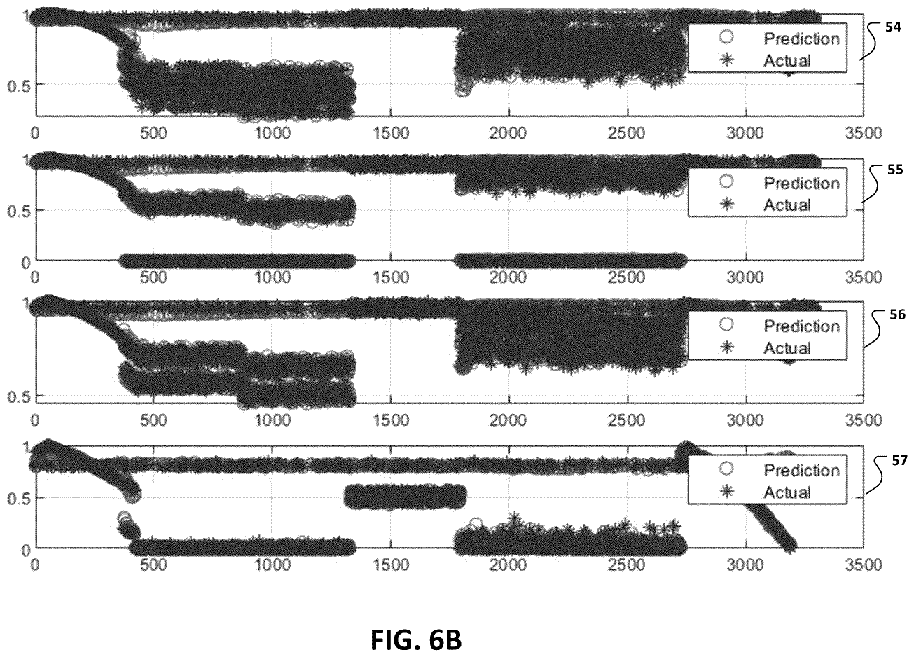

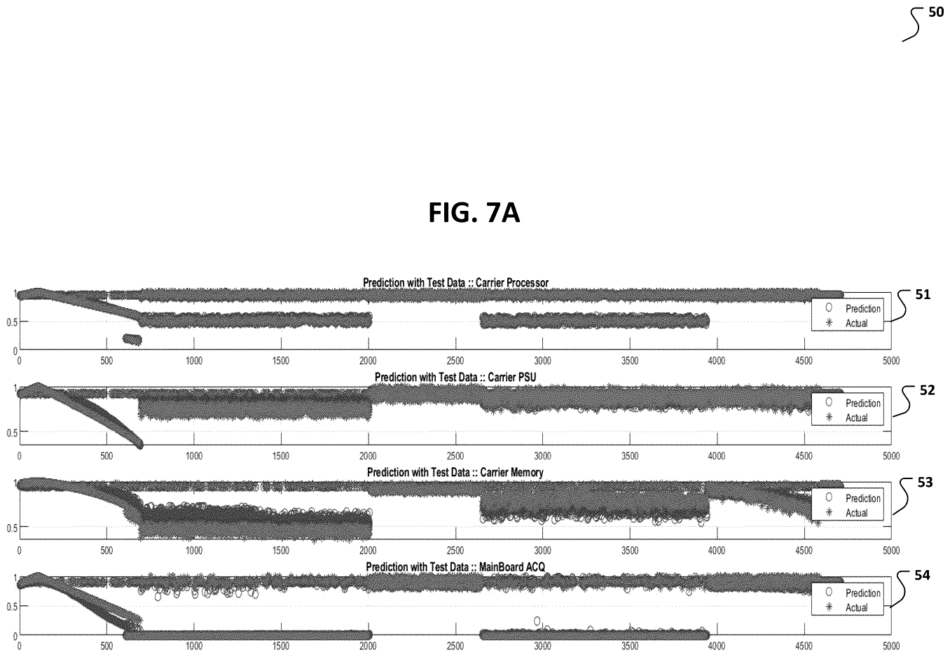

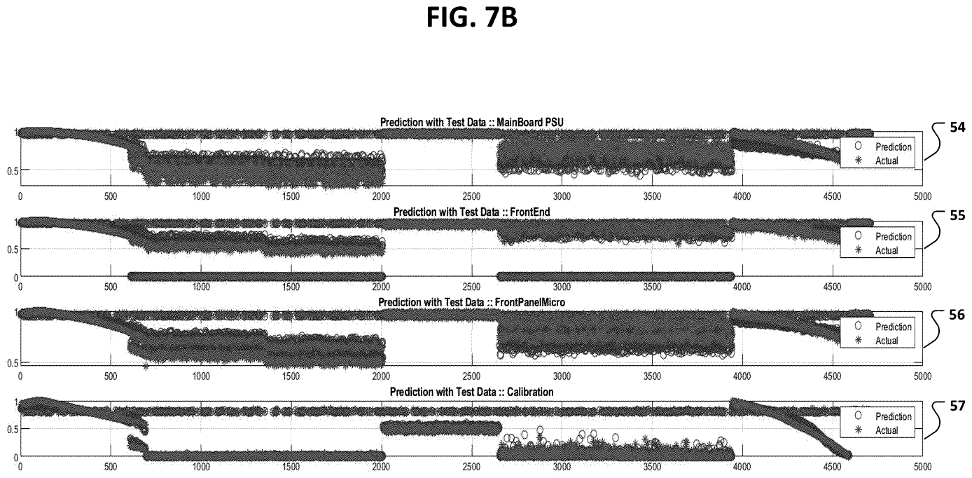

FIGS. 5A and 5B show the training error trend with an iteration loop for different components, in this case the carrier processor 50, the carrier PSU 51, the carrier memory 52, the main board acquisition 53, main board PSU 54, the front end 55, the front panel 56 and the calibration 57. The model underwent 200 iterations to achieve the version with the lowest prediction error. FIGS. 6A-6B show the prediction with the training set corresponding to the same factors listed above. FIGS. 7A-7B show the prediction with respect to the training set corresponding to the same components.

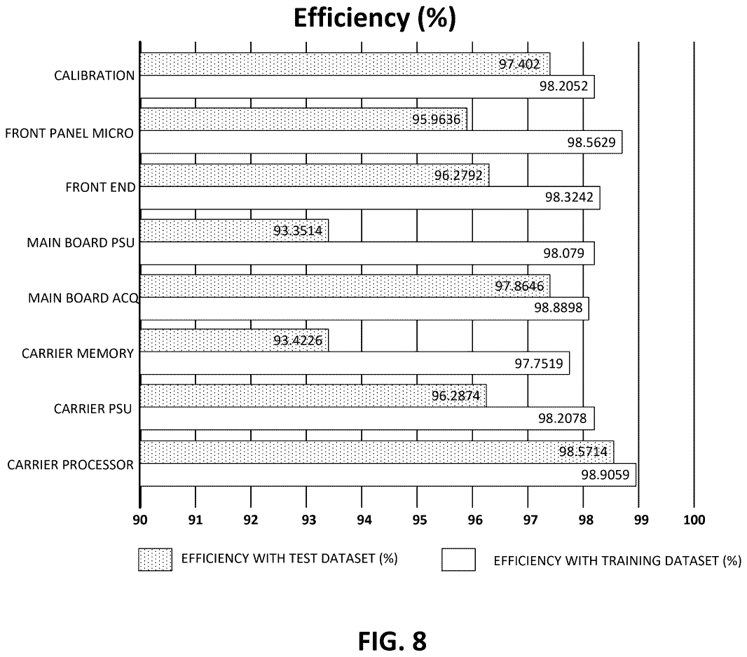

In FIGS. 6A-6B and 7A-7B, one can see that some of the prediction circles are mostly only visible on the edges of the prediction lines, which are the heavier gray areas. This indicates that the model prediction tracks very closely with the actual data. FIG. 8 shows an efficiency graph of the training data set and the test data set.

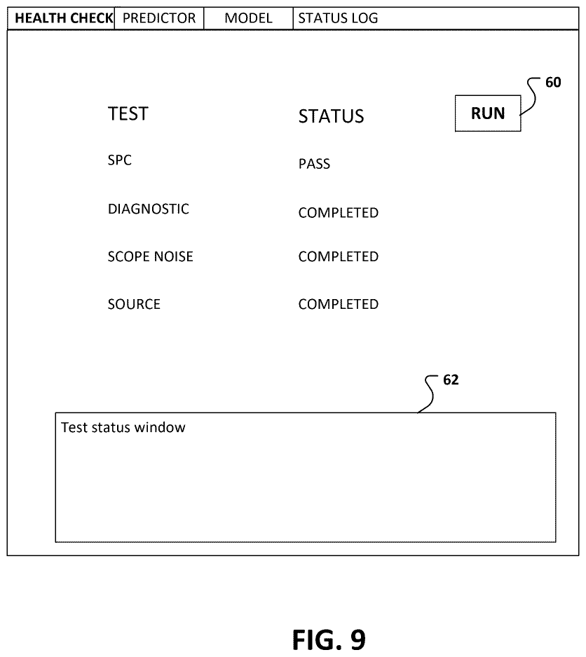

According to some embodiments, the above developed model may be integrated with a user interface, such as the example UIs shown in FIGS. 9 through 11, running on an instrument. FIG. 9 shows an embodiment of a user interface for the health check option tab. FIG. 9 shows the test was run on the SPC parameter and status shows that it passed. The RUN button 60 allows the user to run the test, and the test status window 62 would show the status of the various components as each was tested.

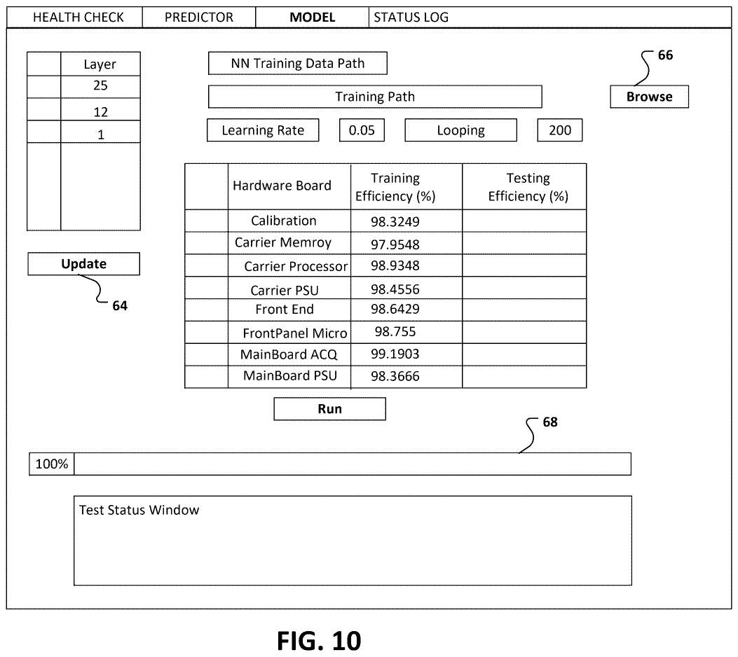

Once the health check test is run, the user moves to the user interface of FIG. 10 that focuses on the model. The user has the ability update the model at 64, and provide the path or browse to the training data at 66. The test status window 68 in this interface would show the error trends. The user selects the model in this interface.

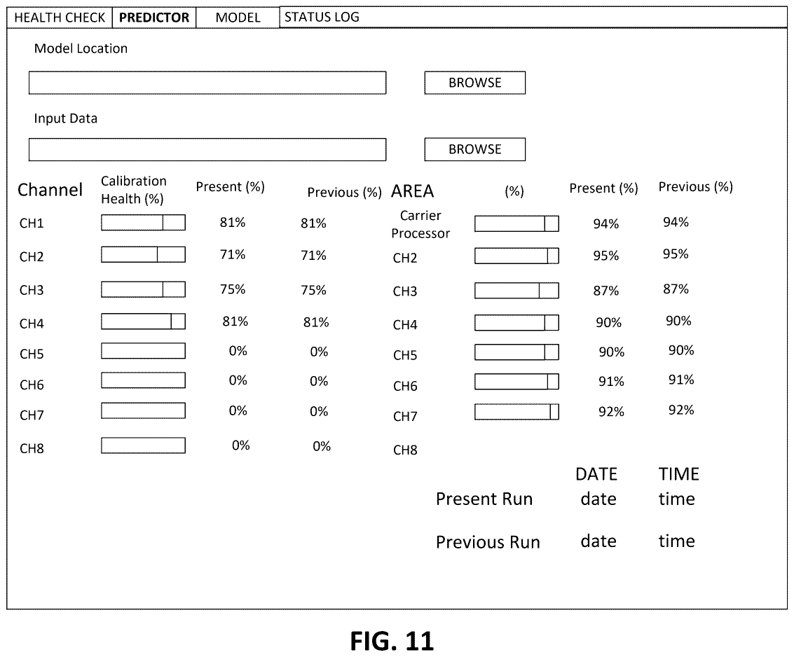

In FIG. 11, the user interface allows the user to browse to the model location, and to provide the input data path. The user then runs the predictor to show the predicted service needs for this instrument. This may allow the service center to adjust operations based upon upcoming service needs.

The table below is an example of data that may be returned from individual heath/service predictor tools running on test and measurement instruments globally, back to a central database system.

| Instrument | Region | Calibration | Hardware Health |
|---|---|---|---|
| MSO4 | Asia | need a calibration | Healthy |
| DPO70000SX | US | Good | Acquisition Board |
| | | | failure |
| MSO6B | China | Good | Good |
| AFG3K | US | need a calibration | |
| . . . (other options) | | | |

One should note that the data requested from customer instrument is only related to Health of instrument. The tool does not require any customer-specific data to transfer to Central Database. Some of the instrument-specific data may comprise the instrument name and location by region, but nothing specific to the customer. The centralization of the data may also be optional. The user could run the health predictor at their location and use it to track the health of their instruments without sending the information to the central service depot database or other repository.

As discussed above, embodiments of the disclosure may provide one or more of the following aspects and advantages.

The Health Predictor offers step-by-step prediction of performance and health degradation. This capability allows users to anticipate issues and maintain their instruments effectively.

When performing a self-test on the MSO ASIC (Acquisition, Signal, or Memory), a failed indication typically means the component is entirely nonfunctional. However, the Health Predictor of the embodiments goes beyond this binary result. It utilizes measured parameters from the present and past to compare health indications. For instance, a Custom Acquisition ASIC might not show any issues, but the health prediction model considers variations in parameters such as scope noise, temperature deviation, and system age to assess overall health.

Another feature of the Health Predictor is its ability to assess calibration health. By analyzing the deviation direction of various measured parameters, the predictor helps users identify calibration needs in advance. In usage locally at the instrument, this may allow users to perform calibration processes that are appropriate for users before deciding whether the instrument needs service center-level calibration.

Unlike self-tests, which do not reveal power distribution system issues on the carrier interface board or main board, the trained Health Predictor can predict the health of the MSO oscilloscope's power distribution system.

The Health Predictor benefits from the expertise of manufacturer hardware and service professionals during model training.

The presented neural network (NN) solution models the nonlinear behavior of individual hardware health in the instrument. It considers both dependent and independent parameters. The predictor also accounts for temperature variations in the ASIC to predict the health of the front-end and main boards. Unlike self-tests, which lack this capability, the prediction model provides insight into system performance direction. The model is trained to factor in electronic hardware aging versus performance, following an exponential function. The system can detect the need for instrument calibration in advance, allowing customers to plan activities ahead of time. The central monitoring system will assist the service team in planning for upcoming work. The model provides early feasibility to the Tektronix service team regarding upcoming hardware board repair needs. As a result, the service team can manage hardware resources in advance.

The proposed solution also predicts the health of individual hardware components, which can be updated to a central server for each region to access the data. The model can also measure overall quality and performance

Aspects of the disclosure may operate on a particularly created hardware, on firmware, digital signal processors, or on a specially programmed general-purpose computer including a processor operating according to programmed instructions. The terms controller or processor as used herein are intended to include microprocessors, microcomputers, Application Specific Integrated Circuits (ASICs), and dedicated hardware controllers. One or more aspects of the disclosure may be embodied in computer-usable data and computer-executable instructions, such as in one or more program modules, executed by one or more computers (including monitoring modules), or other devices. Generally, program modules include routines, programs, objects, components, data structures, etc. that perform particular tasks or implement particular abstract data types when executed by a processor in a computer or other device. The computer executable instructions may be stored on a non-transitory computer readable medium such as a hard disk, optical disk, removable storage media, solid state memory, Random Access Memory (RAM), etc. As will be appreciated by one of skill in the art, the functionality of the program modules may be combined or distributed as desired in various aspects. In addition, the functionality may be embodied in whole or in part in firmware or hardware equivalents such as integrated circuits, FPGA, and the like. Particular data structures may be used to more effectively implement one or more aspects of the disclosure, and such data structures are contemplated within the scope of computer executable instructions and computer-usable data described herein.

The disclosed aspects may be implemented, in some cases, in hardware, firmware, software, or any combination thereof. The disclosed aspects may also be implemented as instructions carried by or stored on one or more or non-transitory computer-readable media, which may be read and executed by one or more processors. Such instructions may be referred to as a computer program product. Computer-readable media, as discussed herein, means any media that can be accessed by a computing device. By way of example, and not limitation, computer-readable media may comprise computer storage media and communication media.

Computer storage media means any medium that can be used to store computer-readable information. By way of example, and not limitation, computer storage media may include RAM, ROM, Electrically Erasable Programmable Read-Only Memory (EEPROM), flash memory or other memory technology, Compact Disc Read Only Memory (CD-ROM), Digital Video Disc (DVD), or other optical disk storage, magnetic cassettes, magnetic tape, magnetic disk storage or other magnetic storage devices, and any other volatile or nonvolatile, removable or non-removable media implemented in any technology. Computer storage media excludes signals per se and transitory forms of signal transmission.

Communication media means any media that can be used for the communication of computer-readable information. By way of example, and not limitation, communication media may include coaxial cables, fiber-optic cables, air, or any other media suitable for the communication of electrical, optical, Radio Frequency (RF), infrared, acoustic or other types of signals.

### EXAMPLES

Illustrative examples of the disclosed technologies are provided below. An embodiment of the technologies may include one or more, and any combination of, the examples described below.

Example 1 is a and measurement instrument, comprising: hardware components, comprising one or more of: one or more system circuit boards; a user interface; a display; a power supply; one or more integrated circuit chips; and a memory; one or more artificial intelligence (AI) models stored in the memory; and one or more processors configured to execute code to cause the one or more processors to operate one of the one or more AI models to receive inputs from at least one of the hardware components and provide an output of predicted service needs for the test and measurement instrument.

Example 2 is the test and measurement instrument of Example 1, further comprising a network interface to allow the test and measurement instrument to establish a communication connection with a server at a service center and send service needs data to the server.

Example 3 is the test and measurement instrument of either of Examples 1 or 2, wherein the code that causes the one or more processors to provide the output of predicted service needs comprises code that causes the one or more processors to provide the output as an internal hardware health of the test and measurement instrument.

Example 4 is the test and measurement instrument of any of Examples 1 through 3, wherein the code that causes the one or more processors to provide the output of predicted service needs comprises code that causes the one or more processors to provide the output as a calibration status of the test and measurement instrument.

Example 5 is the test and measurement instrument of any of Examples 1 through 4, the one or more processors further configured to execute code to cause the one or more processors to display a user interface on the display, the user interface having a health check option to allow a user to cause the one or more processors to perform an instrument self-test that causes the hardware components to generate the inputs to be received by the AI model.

Example 6 is the test and measurement instrument of Example 5, wherein the code that causes the one or more processors to perform an instrument self-test comprises code that generates a known source signal to apply to the hardware components.

Example 7 is the test and measurement instrument of Example 5, wherein the one or more processors are further configured to execute code to: provide a user interface to allow the user to select a selected AI model; and execute the code to cause the one or more processors to operate the selected AI model using the inputs.

Example 8 is the test and measurement instrument of any of Examples 1 through 7, wherein the one or more processors are further configured to execute code to cause the one or more processors to train the one or more AI models.

Example 9 is the test and measurement instrument of any of Examples 1 through 8, wherein the code that causes the one or more processors to train the one or more AI models comprises code that causes the one or more processors to train the one or more AI models on one or more of self-test data and past service history data.

Example 10 is a method of predicting test and measurement instrument health, comprising: receiving inputs from at least one hardware component in the test and measurement instrument; operating one of one or more artificial intelligence (AI) models to receive inputs from the at least one hardware component to provide an output of predicted service needs for the test and measurement instrument; and using the output to identify the test and measurement instrument as needing service depending upon the output.

Example 11 is the method of Example 10, further comprising a network interface to allow the test and measurement instrument to establish a communication connection with a server at a service center and send service needs data to the server.

Example 12 is the method of either of Examples 10 or 11, wherein operating one of the one or more AI models to provide the output of predicted service needs comprises operating one of the one or more AI models to provide the output as an internal hardware health of the test and measurement instrument.

Example 13 is the method of any of Examples 10 through 12, wherein operating one of the one or more AI models to provide the output of predicted service needs comprises operating one of the one or more AI models to provide the output as a calibration status of the test and measurement instrument.

Example 14 is the method of any of Examples 10 through 13, further comprising displaying a user interface on the display, the user interface having a health check option to allow a user to start an instrument self-test that causes the at least one or more hardware component to generate the inputs to be received by the AI model.

Example 15 is the method of Example 14, further comprising generating a known source signal to apply to the hardware component.

Example 16 is the method of Example 14, further comprising: providing a user interface to allow the user to select a selected AI model; and operating the selected AI model using the inputs.

Example 17 is the method of any of Examples 10 through 6, further comprising training the one or more AI models.

Example 18 is the method of any of Examples 10 through 17, training the one or more AI models comprises one or more of self-test data and past service history data.

Example 19 is a test and measurement system, comprising: one or more test and measurement instruments, comprising: hardware components; a user interface; a display; a power supply; one or more integrated circuit chips; a communication interface; a memory; an artificial intelligence (AI) model stored in the memory; and one or more processors configured to execute code to cause the one or more processors to operate the AI model to receive inputs from at least one of the hardware components and provide an output of a predicted service needs for the one or more test and measurement instruments; and one or more service centers having one or more servers in communication with the one or more test and measurement instruments, the servers configured to: receive predicted service needs data, and instrument-specific data from the one or more test and measurement instruments; monitor the predicted service needs data of the one or more test and measurement instruments; and adjust operations of the one or more service centers based upon the predicted service needs based upon the instrument-specific data.

Example 20 is the test and measurement system of Example 19, wherein the servers contain a repository of AI models and the servers are configured to update the one or more AI models in the memory of the one or more test and measurement instruments.

All features disclosed in the specification, including the claims, abstract, and drawings, and all the steps in any method or process disclosed, may be combined in any combination, except combinations where at least some of such features and/or steps are mutually exclusive. Each feature disclosed in the specification, including the claims, abstract, and drawings, can be replaced by alternative features serving the same, equivalent, or similar purpose, unless expressly stated otherwise.

Additionally, this written description makes reference to particular features. It is to be understood that the disclosure in this specification includes all possible combinations of those particular features. For example, where a particular feature is disclosed in the context of a particular aspect, that feature can also be used, to the extent possible, in the context of other aspects.

Also, when reference is made in this application to a method having two or more defined steps or operations, the defined steps or operations can be carried out in any order or simultaneously, unless the context excludes those possibilities.

Although specific aspects of this disclosure have been illustrated and described for purposes of illustration, it will be understood that various modifications may be made without departing from the spirit and scope of the invention. Accordingly, the invention should not be limited except as by the appended claims.

1. A test and measurement instrument, comprising:
hardware components, comprising one or more of:
one or more system circuit boards;
a user interface;
a display;
a power supply;
one or more integrated circuit chips; and
a memory;
one or more artificial intelligence (AI) models stored in the memory; and
one or more processors configured to execute code to cause the one or more processors to operate one of the one or more AI models to receive inputs from at least one of the hardware components and provide an output of predicted service needs for the test and measurement instrument.

2. The test and measurement instrument as claimed in claim 1, further comprising a network interface to allow the test and measurement instrument to establish a communication connection with a server at a service center and send service needs data to the server.

3. The test and measurement instrument as claimed in claim 1, wherein the code that causes the one or more processors to provide the output of predicted service needs comprises code that causes the one or more processors to provide the output as an internal hardware health of the test and measurement instrument.

4. The test and measurement instrument as claimed in claim 1, wherein the code that causes the one or more processors to provide the output of predicted service needs comprises code that causes the one or more processors to provide the output as a calibration status of the test and measurement instrument.

5. The test and measurement instrument as claimed in claim 1, the one or more processors further configured to execute code to cause the one or more processors to display a user interface on the display, the user interface having a health check option to allow a user to cause the one or more processors to perform an instrument self-test that causes the hardware components to generate the inputs to be received by the AI model.

6. The test and measurement instrument as claimed in claim 5, wherein the code that causes the one or more processors to perform an instrument self-test comprises code that generates a known source signal to apply to the hardware components.

7. The test and measurement instrument as claimed in claim 5, wherein the one or more processors are further configured to execute code to:
provide a user interface to allow the user to select a selected AI model; and
execute the code to cause the one or more processors to operate the selected AI model using the inputs.

8. The test and measurement instrument as claimed in claim 1, wherein the one or more processors are further configured to execute code to cause the one or more processors to train the one or more AI models.

9. The test and measurement instrument as claimed in claim 1, wherein the code that causes the one or more processors to train the one or more AI models comprises code that causes the one or more processors to train the one or more AI models on one or more of self-test data and past service history data.

10. A method of predicting test and measurement instrument health, comprising:
receiving inputs from at least one hardware component in the test and measurement instrument;
operating one of one or more artificial intelligence (AI) models to receive inputs from the at least one hardware component to provide an output of predicted service needs for the test and measurement instrument; and
using the output to identify the test and measurement instrument as needing service depending upon the output.

11. The method as claimed in claim 10, further comprising a network interface to allow the test and measurement instrument to establish a communication connection with a server at a service center and send service needs data to the server.

12. The method as claimed in claim 10, wherein operating one of the one or more AI models to provide the output of predicted service needs comprises operating one of the one or more AI models to provide the output as an internal hardware health of the test and measurement instrument.

13. The method as claimed in claim 10, wherein operating one of the one or more AI models to provide the output of predicted service needs comprises operating one of the one or more AI models to provide the output as a calibration status of the test and measurement instrument.

14. The method as claimed in claim 10, further comprising displaying a user interface on the display, the user interface having a health check option to allow a user to start an instrument self-test that causes the at least one or more hardware component to generate the inputs to be received by the AI model.

15. The method as claimed in claim 14, further comprising generating a known source signal to apply to the hardware component.

16. The method as claimed in claim 14, further comprising:
providing a user interface to allow the user to select a selected AI model; and
operating the selected AI model using the inputs.

17. The method as claimed in claim 10, further comprising training the one or more AI models.

18. The method as claimed in claim 10, training the one or more AI models comprises one or more of self-test data and past service history data.

19. A test and measurement system, comprising:
one or more test and measurement instruments, comprising:
hardware components;
a user interface;
a display;
a power supply;
one or more integrated circuit chips;
a communication interface;
a memory;
an artificial intelligence (AI) model stored in the memory; and
one or more processors configured to execute code to cause the one or more processors to operate the AI model to receive inputs from at least one of the hardware components and provide an output of a predicted service needs for the one or more test and measurement instruments; and
one or more service centers having one or more servers in communication with the one or more test and measurement instruments, the servers configured to:
receive predicted service needs data, and instrument-specific data from the one or more test and measurement instruments;
monitor the predicted service needs data of the one or more test and measurement instruments; and
adjust operations of the one or more service centers based upon the predicted service needs based upon the instrument-specific data.

20. The test and measurement system as claimed in claim 19, wherein the servers contain a repository of AI models and the servers are configured to update the one or more AI models in the memory of the one or more test and measurement instruments.
